(19) United States
(12) Patent Application Publication
(10) Pub. No.: US 2026/0197000 A1
(43) Pub. Date: Jul. 9, 2026

(54) MAGNETIC METAL PROXIMITY ELECTRIC SWITCH

(71) Applicant: Daniel Kilsdonk, Westford, MA (US)

(72) Inventor: Daniel Kilsdonk, Westford, MA (US)

(21) Appl. No.: 19/558,127

(22) Filed: Mar. 5, 2026

(51) Int. Cl. H03K 17/95; H01H 1/02; H01H 3/00; H01H 9/30; H01H 36/00

(52) U.S. Cl. CPC H03K 17/9505; H01H 1/0201; H01H 9/30; H01H 36/002; H01H 36/0033; H01H 2003/008; H01H 2009/307; H01H 2036/0086; H01H 2201/012

(57) ABSTRACT

A proximity switch that can be actuated by the nearby presence of a magnetic material such as ferrous metals.

### FIELD OF INVENTION

The present application relates to an electrical switch device, particularly one that is actuated by the nearby presence of a magnetic material such as ferrous metals.

### BACKGROUND OF INVENTION

Electrically, a switch operates by transitioning between at least two discrete states: The Closed state or “ON” wherein conductive contacts are in physical contact, creating a low resistance path that allows current to flow according to Ohm's law and the surrounding circuit impedance, and the Open state or “OFF” wherein contacts are physically separated, introducing a high (ideally infinite) resistance that interrupts current flow.

Mechanically, a switch state is changed between the two states by actuation that is provided as a force translation and motion control system that converts user or actuator input into controlled contact movement with defined force, speed, and travel.

For simplicity, one conductive contact is part of a moveable assembly and the other is part of an immoveable assembly.

The motion control system uses the actuator to move the moveable contact assembly such that its electrical contact touches and therefore makes an electrical connection (“ON state”) between it and the immoveable assembly contact.

The motion control system can also actuate the moveable contact assembly such that it does not touch and therefore removes the electrical connection with the immoveable contact assembly contact thereby changing the state of the electrical connection to the “OFF state”.

Actuation methods heretofore are provided by physical contact (ie, a common house wall switch or door bell button) or by using the magnetic force provided by an external magnet to move the moveable contact (reed switch).

In the case of the reed switch, the two contacts are affixed to reeds that are made of magnetic material, that is, material such as ferrous metals which reacts to magnetism provided by a magnet, such that the electrical contact affixed to or integrated with the moveable reed comes into contact with the immoveable reed contact.

The reed switch is impractical for systems where the expense or availability of an external magnet for actuating the electrical switch is restrictive or expensive.

The current application remedies this limitation by integrating the magnet within the switch itself such that it can detect the movement or proximity of any magnetic material (ie ferrous metals) and change the state of the electrical switch.

The conductive elements (contacts) are typically made from copper alloys, silver, gold, or plated composites to balance conductivity, wear resistance, and corrosion resistance.

Other parts of the contact assemblies are isolated electrically from their respective electrical contacts.

### SUMMARY OF THE INVENTION

By providing a electrical switch actuated by its sensitivity to nearby magnetic materials such as but not limited to ferrous metals, the switch can be actuated without physical touch and without the expense and complication of an external magnet.

The disclosed exemplary embodiments provide a device which works to actuate an electrical switch with only a magnetic material presented nearby such as ferrous metals.

### BRIEF DESCRIPTION OF DRAWINGS

The foregoing will be apparent from the following more particular description of example embodiments of the invention, as illustrated in the drawings in which like reference characters refer to the same parts throughout the different views. The drawings are not necessarily to scale, emphasis instead being placed upon illustrating embodiments of the present invention.

FIG. 1 depicts the components of an example embodiment system 100.

FIG. 2 depicts the mechanical state of an example embodiment system 101 wherein the switch is in the “OFF” position.

FIG. 3 depicts the mechanical state of an example embodiment system 102 wherein the switch is in the “ON” position.

### DETAILED DESCRIPTION

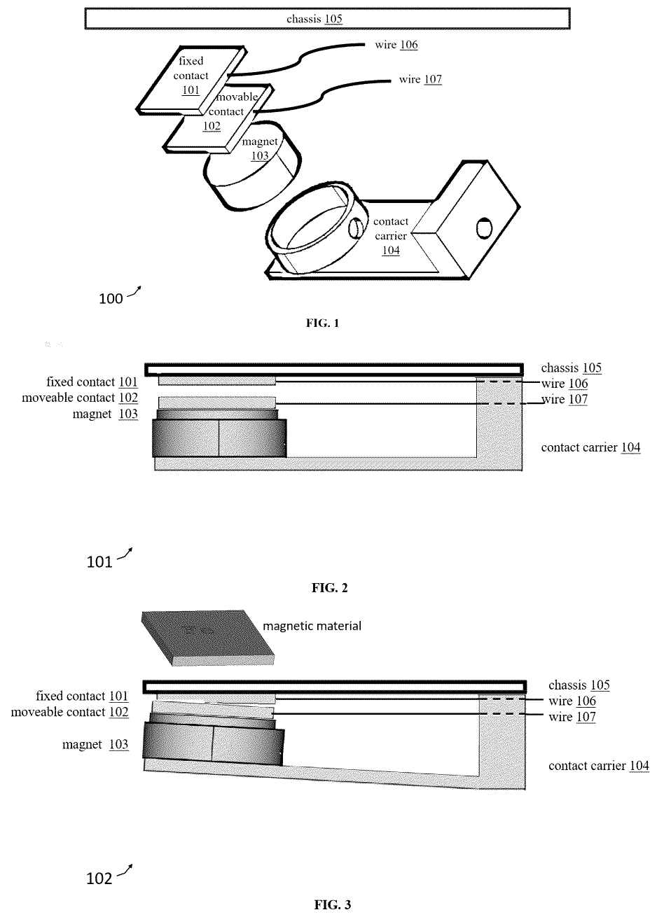

The system 100 of FIG. 1 includes a chassis component 105 which may be part of the system to which the invention is attached which is ideally nonmagnetic. For many electronic products, the chassis component 105 might well be the plastic case within which the working parts of the electronic product reside. The system 100 includes a fixed contact component 101 which may be affixed to the inside of the chassis component 105. The fixed contact component 101 material is electrically conductive. Generally, a wire component 106 provides easy access to the electricity or lack thereof presented at fixed contact component 101 for a first circuit terminal. A moveable contact component 102 is affixed to the top of magnet component 103 and is also electrically conductive. Generally, a wire component 107 provides easy access to the electricity or lack thereof presented at fixed contact component 102 for a second circuit terminal. The system 100 also includes a magnet component 103 which is affixed to a contact bearer component 104. The contact bearer component 104 may provide a receptacle for the magnet. The contact bearer component 104 is also affixed to the chassis component 105.

The placement of the contact bearer component 104 and the fixed contact component labelled 101 are oriented such that the contact bearer component 104 can be flexed such that moveable contact component 102 can touch the fixed contact component 101 but allows for a gap between the two which defines the “OFF” switch state as seen in FIG. 2. In one embodiment, plastic is used to facilitate the flexibility of the contact bearer component 104.

In one embodiment, gravity can induce the contact bearer component to return to “OFF” switch state in embodiments wherein the application geometry allows the fixed contact component 101 to be above the moveable contact component 102.

In another embodiment, a compression spring can induce the contact bearer component to return to “OFF” switch state.

In another embodiment, the material for which the contact bearer is formed, for example plastic, can induce the contact bearer component to return to “OFF” switch state in embodiments wherein the application geometry allows the fixed contact component 101 to be above the moveable contact component 102.

The placement of the contact bearer component 104 and the fixed contact component 101 are oriented such that when a magnetic material such as ferrous metals is placed in proximity to the chassis component 105, the magnet, attracted to the magnetic material such as ferrous metals, moves the contact bearer component 104 to which it is affixed, towards the fixed contact component 101 such that the moveable contact component 102 touches the fixed contact component 101 and electrical conductivity is attained between electrical contacts 101 and 102 and conductivity is thereby produced between wire component 106 and wire component 107 as show in FIG. 3.

In another embodiment, the magnet itself is electrically conductive and is the moveable electrical contact itself. For example, a magnet formed of magnetic material such as ferrous metals does not require a contact to be affixed but can serve as both the magnet and associated electrical contact.

In another embodiment, the magnetic metal proximity switch is enclosed within a tube evacuated or filled with inert gas in order to enhance reliability and workable life of expensive electrical contact material.

While example embodiments have been particularly shown and described, it will be understood by those skilled in the art that various changes in form and details may be made therein without departing from the scope of the embodiments encompassed by the appended claims.

What is claimed is:

1. A magnetic metal proximity switch comprising:
a chassis formed from an electrically insulating material; and
at least one fixed contact electrically coupled to a first circuit terminal; and
at least one movable contact electrically coupled to a second circuit terminal; and
a contact bearer integrated with the moveable contact(s) for substantially collinear movement between the fixed and integrated with the moveable contact(s); and
a magnet actuator formed from a magnet attached to the contact bearer and forming a magnetic coupling from the presence of nearby magnetic material such as ferrous metals to the contact bearer; and
at least one biasing element arranged to apply a restoring force opposing movement of any magnetic coupling and to urge the movable contact toward a predetermined position,
wherein the movable contact is selectively positionable between an open position in which the movable contact is spaced apart from the fixed contact to interrupt electrical continuity between the first and second circuit terminals, and a closed position in which the movable contact is in conductive engagement with the fixed contact to establish electrical continuity between the first and second circuit terminals.

2. The magnetic metal proximity switch of claim 1, wherein the biasing element is formed from a plastic formed contact bearer.

3. The magnetic metal proximity switch of claim 1, wherein the biasing element comprises a compression spring positioned between the chassis and the contact bearer.

4. The magnetic metal proximity switch of claim 1, wherein the biasing element applies a predetermined normal force away from the movable contact when the movable contact is in the closed position.

5. The magnetic metal proximity switch of claim 1, wherein the magnetic actuator is configured to return to a released position when an external actuation force is removed.

6. The magnetic metal proximity switch of claim 1, wherein the invention is enclosed in a tube evacuated or filled with an inert gas.

7. The magnetic metal proximity switch of claim 1, wherein the switch is configured as a momentary contact switch such that the movable contact remains in the closed position only while the magnetic actuator is operable due to magnetic coupling between the magnet and the presence of nearby magnetic material such as ferrous metals.

8. The magnetic metal proximity switch of claim 1, wherein the switch is configured as a latching switch such that successive actuations of the magnetic actuator alternately position the movable contact in the open position and the closed position.

9. The magnetic metal proximity switch of claim 1, further comprising a snap action mechanism operatively associated with the contact bearer or the biasing element.

10. The magnetic metal proximity switch of claim 7, wherein the snap action mechanism is configured to cause the movable contact to transition between the open position and the closed position at a rate greater than a rate of movement of the magnetic actuator.

11. The magnetic metal proximity switch of claim 1, wherein the chassis defines a guide structure configured to constrain movement of the pushbutton actuator substantially along the actuation axis.

12. The magnetic metal proximity switch of claim 1, wherein the chassis includes one or more mechanical stops configured to limit travel of the pushbutton actuator.

13. The magnetic metal proximity switch of claim 1, wherein the fixed contact and the movable contact are formed from a conductive metal or metal alloy.

14. The magnetic metal proximity switch of claim 1, wherein the movable contact and the fixed contact are configured to reduce electrical arcing during separation by controlling a contact separation speed.

15. The magnetic metal proximity switch of claim 1, wherein the chassis is configured to electrically isolate the fixed contact and the movable contact from an external environment.

16. The magnetic metal proximity switch of claim 1, wherein the contact bearer is configured to maintain alignment between the movable contact and the fixed contact during actuation.

17. The magnetic metal proximity switch of claim 1, wherein the magnetic actuator provides tactile feedback to a user during transition between the open position and the closed position.
